(19) United States
(12) Patent Application Publication
(10) Pub. No.: US 2014/0238467 A1
(43) Pub. Date: Aug. 28, 2014

(54) SOLAR POWERED CONTAINER

(71) Applicants: John R. Martin, Ocean City, MD (US); Ramses Torres, Bayamon, PR (US)

(72) Inventors: John R. Martin, Ocean City, MD (US); Ramses Torres, Bayamon, PR (US)

(73) Assignee: Solar Power Innovations, LLC., Ocean City, MD (US)

(21) Appl. No.: 13/780,309

(22) Filed: Feb. 28, 2013

(51) Int. Cl. H01L 31/042; H01L 31/058; H01L 31/052

(52) U.S. Cl. CPC H01L 31/0422; H01L 31/052; H01L 31/0586
USPC 136/248; 136/246; 136/251

(57) ABSTRACT

A portable solar energy generation system that has a disassembled configuration and an assembled configuration. The system includes a solar energy generation assembly, and portable container. The system may further include an internal frame, a power inverter, charge controller, batteries, attachment components, wires, user input devices, fluid tank, turbine, pump, generator, and other system components. When in the disassembled configuration, all system components including the solar energy generation assembly are packaged within the portable container. When in the disassembled configuration, the solar energy generation assembly is coupled to an external surface of the container and is either generating electricity within the container or redirecting sunlight for electricity generation at a predetermined target.

### CROSS-REFERENCE TO RELATED APPLICATION

n/a

### STATEMENT REGARDING FEDERALLY SPONSORED RESEARCH OR DEVELOPMENT

n/a

### FIELD OF THE INVENTION

The present invention relates to a method and system for providing mobile energy generation units.

### BACKGROUND OF THE INVENTION

Many nations of the world, including the United States, places a high importance on finding renewable energy sources that will eliminate or at least mitigate dependence on fossil fuels. Indeed, according to one report by the Frankfurt School UNEP Collaborating Centre for Climate & Sustainable Energy Finance, global investment in renewable energy increased by 17% in 2011 to an all-time high of $257 billion. According to the same report, the total investment in solar power increased by 52% to $147 billion in 2011.

Although is it agreed that renewable energy systems are important, the implementation of such can be difficult. For example, commercial wind farms can be inefficient and take up valuable acreage. Commercial solar parks also take up land that could otherwise be used for farming, land development, or biodiversity. Most of the common renewable energy systems include fixed, permanent energy generation units. For example, most solar parks use ground mounted arrays. These units cannot be moved from the general location to optimize energy production based on fluctuating environmental conditions, to temporarily turn over the land for other uses, or to allow for mobile energy production.

Additionally, most wind energy systems are expensive and inconvenient. Many developing countries, although strongly interested in renewable energy, lack the means and infrastructure for putting large areas of land in energy production. Likewise, installing renewable energy systems in remote locations can be difficult if not impossible. Even residential renewable energy systems, for example, roof solar panels, are costly and can be unattractive and intrusive.

### SUMMARY OF THE INVENTION

The present invention advantageously provides a method and system for portable energy generation systems that may be installed in remote locations, temporary locations, and mobile locations in a cost- and space-effective manner. The system may include a portable container having an outer surface and an inner surface and defining an internal space, and one or more solar energy generation assemblies. The portable energy system may have a disassembled configuration and an assembled configuration, the one or more solar energy generation assemblies being removably coupled to the external surface of the portable container and producing electricity when the system is in the assembled configuration. The system may further include an internal frame. For example, the internal frame may be coupled to the container with the internal space, and the solar energy generation assembly may be coupled to the internal frame when the portable energy system is in the assembled configuration. The system may further include further comprising a shaft and a stabilization ring, the shaft being coupled to the internal frame, passing through the stabilization ring, and extending beyond the outer surface of the container. For example, the shaft may extend from the container top portion in a direction that is substantially orthogonal to the plane of the container top portion. The internal space of the container may be sized to contain the one or more solar energy generation assemblies when the system is in the disassembled configuration. The portable energy generation system may also include a solar tracking assembly coupled to each of the one or more solar energy generation assemblies. Each of the one or more solar energy generation assemblies may include a plurality of photovoltaic cells and a frame, may be a solar thermal collector, or may include one or more reflective elements capable of redirecting sunlight to a predetermined target.

The system may be sold as a kit for the production of solar energy. The kit may include a substantially hollow and portable container, at least one solar energy generation assembly, at least one internal frame, at least one solar tracking assembly, at least one battery, the container being sized to accommodate within the at least one solar energy generation assembly, the at least one internal frame, the at least one solar tracking assembly, and the at least one battery. The kit may also include at least one power inverter, at least one charge controller, and attachment components, also being able to fit within the container. Additionally or alternatively, the kit may also include at least one fluid tank, at least one pump, at least one rotary mechanical device, at least one generator, and attachment components, at least one gas generator, at least one diesel generator, and/or at least one fuel cell, all of which being able to fit within the container.

### BRIEF DESCRIPTION OF THE DRAWINGS

A more complete understanding of the present invention, and the attendant advantages and features thereof, will be more readily understood by reference to the following detailed description when considered in conjunction with the accompanying drawings wherein:

FIG. 1 shows a first embodiment of a portable energy generation system;

FIG. 2A shows a solar energy generation assembly affixed to an internal frame;

FIGS. 2B and 2C show a front and side view of a solar energy generation assembly affixed to an internal frame, the internal frame being affixed to and within the container;

FIG. 2D shows a close-up view of a stabilization ring as shown in FIGS. 2A and 2B;

FIG. 2E shows a cross-sectional view of the stabilization ring and shaft as shown in FIGS. 2A and 2B;

FIG. 3 shows a second embodiment of a portable energy generation system;

FIG. 4 shows a third embodiment of a portable energy generation system;

FIG. 5 shows a fourth embodiment of a portable energy generation system;

FIG. 6 shows a fifth embodiment of a portable energy generation system;

FIG. 7 shows a first exemplary configuration of a plurality of portable energy generation systems;

FIG. 8 shows a second exemplary configuration of a plurality of portable energy generation systems;

FIG. 9 shows a third exemplary configuration of portable energy systems; and

FIG. 10 shows a fourth exemplary configuration of portable energy systems.

### DETAILED DESCRIPTION OF THE INVENTION

As used herein, the term “solar energy generation assembly” generally refers to any device or combination of devices capable of directly or indirectly converting sunlight or solar heat into electricity. For example, a solar energy generation assembly may be a solar module, photovoltaic array, heliostat and predetermined target, solar thermal collector, or the like.

As used herein, the term “photovoltaic cell” refers to an electrical device that converts light energy or photons into electricity though the photovoltaic effect. When exposed to light, a photovoltaic cell can generate and support and electric current without being attached to an external voltage source.

As used herein, the term “solar module” refers to a connected assembly of photovoltaic cells. The solar module may be planar or substantially planar (for example, a “solar panel”), or may have any shape that maximizes the solar module's exposure to light energy. Each solar module may be independent or a component of a photovoltaic system.

As used herein, the term “photovoltaic array” refers to a linked collection of solar modules. An array may refer to, for example, a plurality of linked solar modules on a single panel or a linked collection of multiple panels or solar energy generation assemblies.

As used herein, the term “tracker” refers to a device that orients a solar module, reflective element, lens, or the like toward the sun. A tracker may have one or more degrees of freedom that act as axes of rotation (for example, single-axis trackers and dual-axis trackers).

As used herein, the term “power tower” or “solar power tower” refers to a predetermined target or central collection device for the redirection of light from one or more heliostats. The power tower may include one or more photovoltaic cells and/or use the redirected light to heat a body of fluid that powers a turbine or other rotary mechanical device that, in turn, powers a generator that produces electricity.

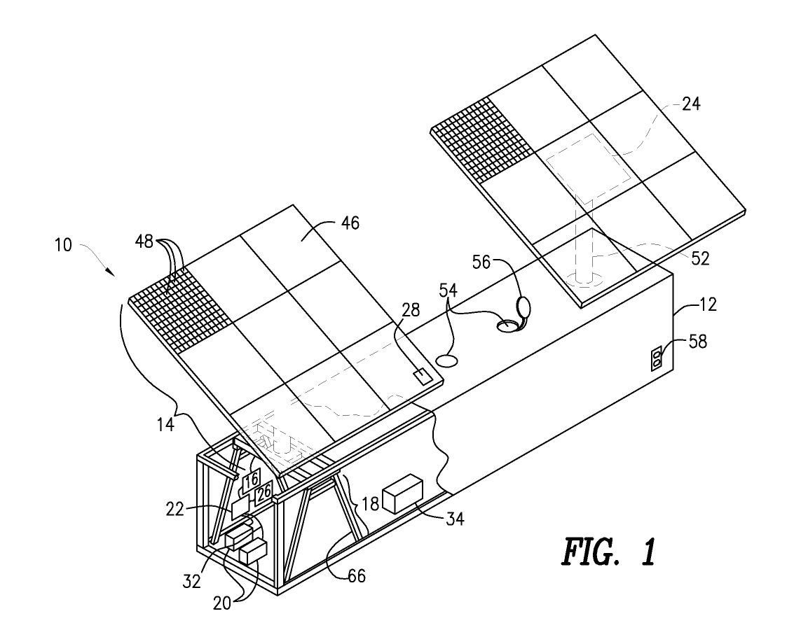

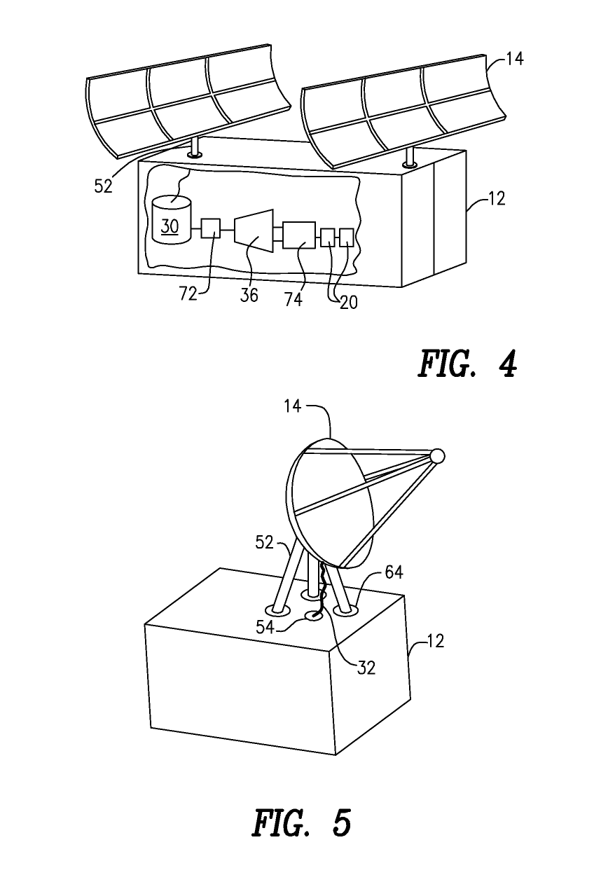

Referring now to FIG. 1, a first embodiment of a portable energy generation system is shown. The portable energy generation system 10 may generally include a container 12, one or more solar energy generation assemblies 14, a power inverter 16 (as a non-limiting example, the system 10 may include two 5,000-watt power inverters 16), and an internal frame 18. The portable energy generation system may also include one or more batteries 20, a charge controller 22, one or more tracking assemblies 24, one or more user control devices, computers, or user input devices 26, sensors (such as temperature or pressure sensors) 28, fluid tanks 30 (for example, as shown in FIG. 4), and/or wires or cables 32, conduits, and other components for anchoring, assembling, operating, monitoring, or linking the system 10.

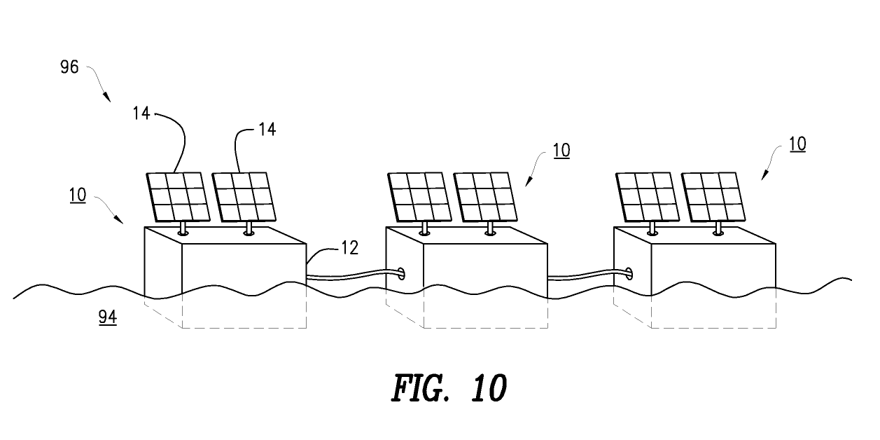

The container 12 may be any rigid-sided container that is sized to accommodate all the components of the portable energy generation system 10, including the one or more solar energy generation assemblies 14. As a non-limiting example, the container 12 may be the typical size and shape of a shipping container, for example, approximately 40 feet in length by approximately eight feet in height and in width. Alternatively, other container sizes and configurations may be used, depending on the size and amount of components that must fit within, the method of transportation, and the area of the desired location at which the system 10 will be assembled for use. The container 12 may be camouflaged, labeled, and/or may have a textured, reflective, or non-reflective surface. Additionally, the container 12 may be buoyant so as to support the one or more solar energy generation assemblies 14 (for example, as shown in FIG. 10) while the container 12 is floating in a body of water.

The portable energy generation system 10 is transportable as a self-contained kit to the desired location. Once at the desired location, the portable energy generation system 10 is assembled. The one or more solar energy generation assemblies 14 are disposed on the outer surface of the container 12. Electrical components such as wires 32, power inverter 16, batteries 20, and charge controller 22 may be housed within the container 12 when the system 10 is assembled, thus being protected from the elements, vandals, or other interference. Even with the electrical components being housed within the container 12, a substantial volume of the container 12 may be available for storage of other items or as temporary sleeping quarters or weather shelter. Additionally or alternatively, the at least partially empty container may be used to house other energy sources 34 (as shown in FIG. 1), such as gas or diesel generators, fuel cells, batteries, to create a constant energy source even when no electricity is being generated by the one or more solar energy generation assemblies 14.

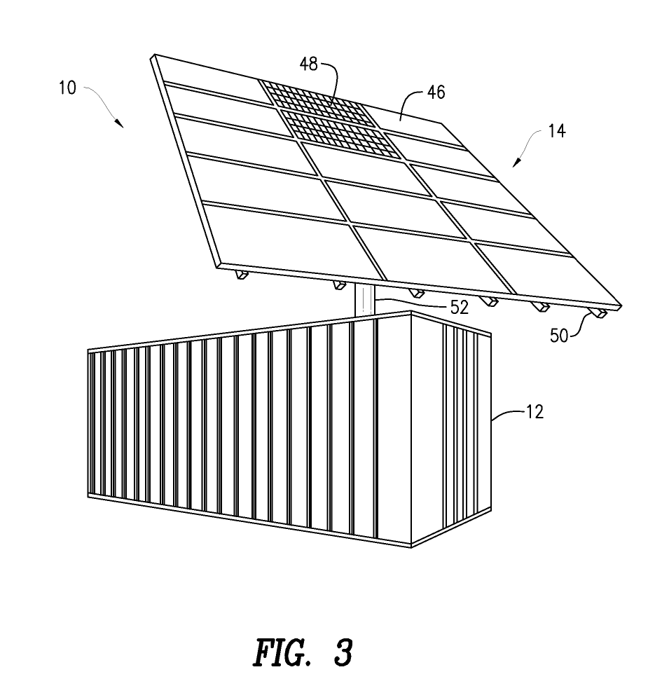

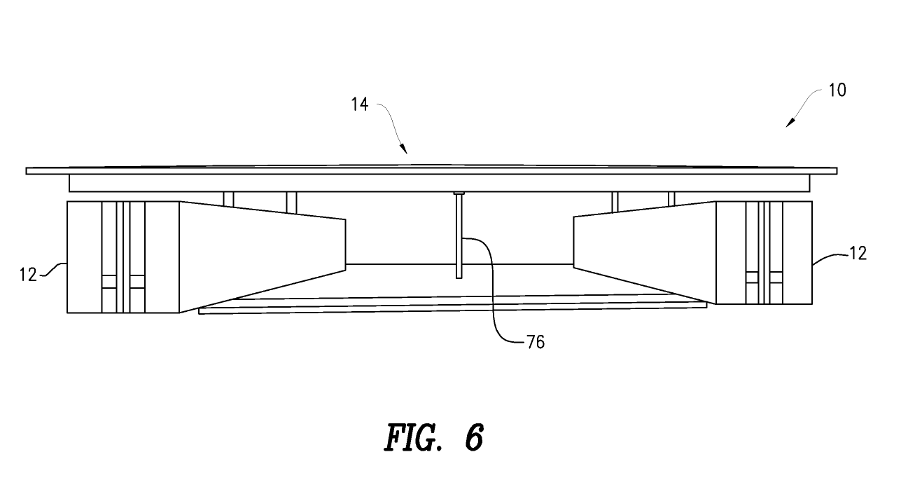

Continuing to refer to FIG. 1, each of the one or more solar energy generation assemblies 14 may include any device or combination of devices capable of directly converting sunlight or solar heat into electricity. This includes, but is not limited to, photovoltaic cells, solar modules, solar thermal collectors (for example, flat plate collectors, parabolic troughs, and parabolic dishes), or heliostats with associated predetermined target (for example, a power tower having one or more photovoltaic cells or fluid tanks for the storage of heat and/or production of electricity). For devices that indirectly product electricity by heating water to steam and using the steam to drive a turbine or motor 36 (as shown, for example, in FIGS. 4 and 5), or by the use of liquid sodium, molten salts, or other energized liquid, the system 10 may also include one or more tanks 30 (for example, as shown in FIG. 4) associated with the one or more solar energy generation assemblies 14 for holding the fluid. The system 10 may include one or more solar energy generation assemblies 14. For example, one assembly per system 10 is shown in FIGS. 3 and 6, and two assemblies 14 per system 10 are shown in FIGS. 1, 5, and 7-10.

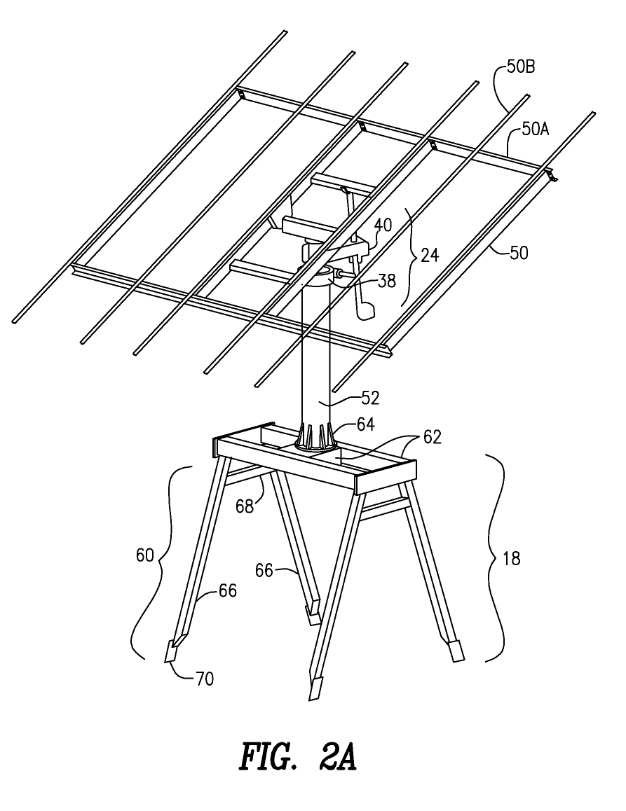

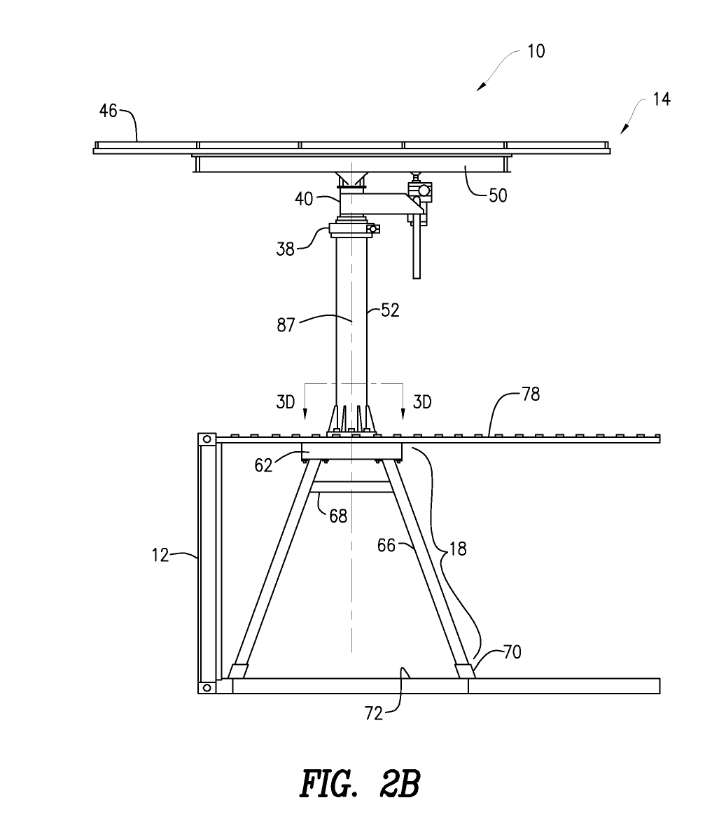

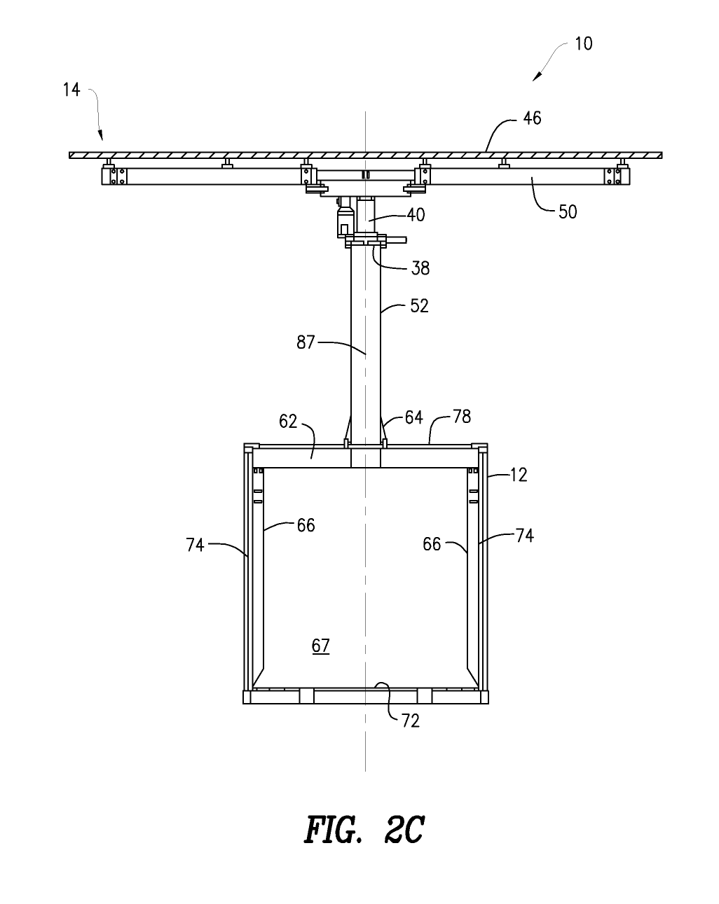

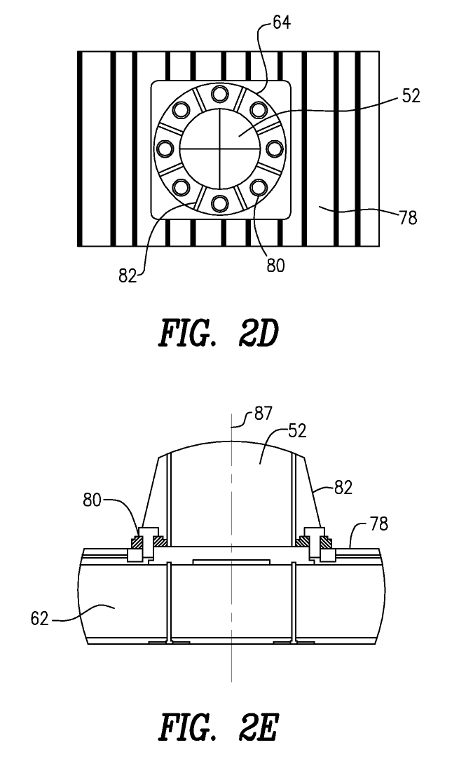

The one or more solar energy generation assemblies 14 may be “trackers” capable of following the sun across the sky for optimal collection of solar energy. These trackers each have a tracking assembly 24 that may include a dual-axis slew drive 38 and a slew drive movement controller 40 (as shown in FIG. 2), as well as other components, for orienting a plurality of solar modules 46 of the solar energy generation assembly 14 in a direction where the most sunlight is received. The tracking assembly 24 may be in communication with one or more computers and/or user input devices 26 for controlling and timing the movement of the one or more solar energy generation assemblies 14.

Referring again to FIG. 1, each solar energy generation assembly 14 may include a plurality of solar modules 46 that each includes a plurality of photovoltaic cells 48, a photovoltaic frame 50, and a shaft 52. The photovoltaic frame 50 may be coupled to the tracker assembly 24 (for example, as shown in FIG. 2) and/or the shaft 52. As a non-limiting example, each solar energy generation assembly 14 shown in FIG. 1 includes fifteen solar modules 46 each including 260 photovoltaic cells 48. However, it will be understood that number of solar modules 46 and photovoltaic cells 48 may be used as determined by available container volume, desired location area, energy needs, and cost restrictions. For example, each solar module 46 may include between 60 to 72 photovoltaic cells 48, although more or fewer photovoltaic cells 48 could be used. For simplicity, individual photovoltaic cells 48 may only shown in one solar module 46 of each solar energy generation assembly 14 in the figures, although it will be understood that each solar module 46 may include a plurality of photovoltaic cells 48. As a non-limiting example, each solar module 46 as shown in FIG. 1 may be approximately 77 in by approximately 39 in, and may generate between approximately 200 watts to approximately 500 watts of power at full sun. However, it will be understood that smaller arrays may produce less power and larger arrays may produce more power, assuming normal conversion inefficiencies and weather that produces cloud cover and shade.

The one or more solar energy generation assemblies 14 may be sized to fit within the container 12 when disassembled. Once the system 10 is at the desired location, the solar modules 46 and photovoltaic frame 50 may be assembled and removably coupled to an outer surface of the container 12. For example, the solar modules 46 and photovoltaic frame 50 may be coupled to the container 12 using bolts, screws, tracks, gaskets, clamps, clips, magnets, straps, bands, nails, etc., or by welding or other suitable means. Further, the system 10 may include an internal frame 18 for each solar generation assembly 14, such that the internal frame 18 is disposed on the inside of the container 12 and the solar generation assembly 14 is disposed on the outside of the outside of the container 12 and coupled to the internal frame 18. For example, the solar generation assembly 14 may be coupled to the internal frame 18 as shown and described in FIGS. 2A-2C, with the solar generation assembly 14 being disposed on the outside of the container 12. One or more walls of the container 12 may have pre-cut holes, slots, or other apertures 54 through which wires 32 may be fed from the one or more solar energy generation assemblies 14 into the container 12. Alternatively, although container 12 may have pre-cut apertures 54, the wires 32 may be disposed within the shaft 52 of the solar generation assembly 14. When all components are packaged or housed within the container 12 or when a particular aperture 54 is not being used, each of the one or more apertures 54 may have a plug (as shown in FIG. 1), hinged cover, or other means 56 for being sealed to protect the interior of the container 12 from the environment (such as moisture, dust, rain, insects, or the like).

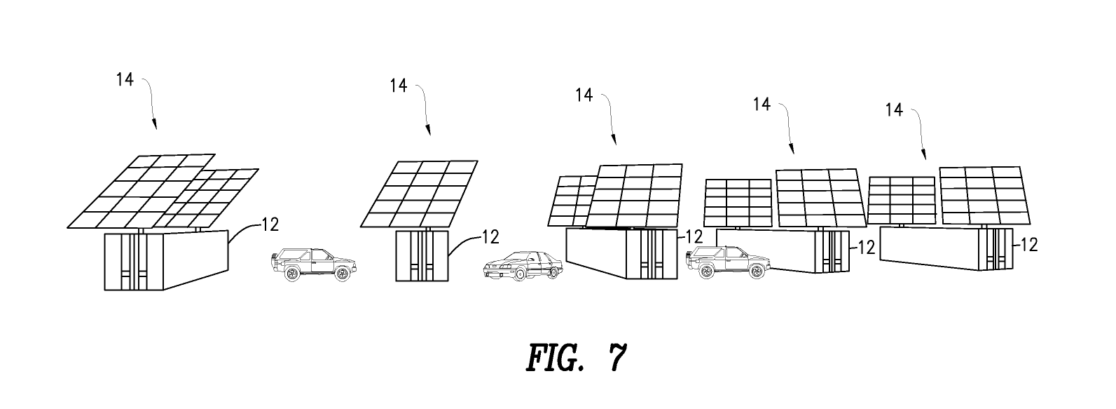

When assembled and operational, each of the one or more solar energy generation assemblies 14 may be in electrical communication with the power inverter 16, one or more batteries 20, and charge controller 22. The one or more assemblies 14 may also be in electrical communication with one or more computers or user input devices 26 and, depending on the type of solar energy generation assembly 14 being used, fluid communication with one or more fluid tanks 30 (for example, as shown in FIG. 4). Further, each energy generation system 10 may be in communication with each other to create a larger array (for example, as shown in FIGS. 7, 8, and 10) or each system 10 may generate and/or store electricity independently of other systems 10.

As electricity is generated by each of the one or more solar energy generation assemblies 14, the electricity may move along the one or more wires 32 to the charge controller 22 (which prevents overcharging of the batteries 20) and then to the batteries 20, where the electricity can be stored and/or from where other appliances or devices may be powered. The container 12 optionally may have a plug or outlet 58 mounted on an interior or external surface of the container 12 that is in electrical communication with the one or more batteries 20 (for example, as shown in FIG. 3. Additionally, each system 10 may store energy in the batteries 20 contained within, or multiple systems 10 may be connected so that electricity may be distributed between the systems 10. For example, electricity generated by a first system 10 may be sent to and stored within batteries 28 contained within a second system 10.

Continuing to refer to FIG. 1, the system 10 may optionally include one or more sensors 28, such as temperature and/or pressure sensors. Each sensor 28 may be located at any part of the system; for example, a temperature sensor may be located proximate and in operable communication with a solar energy generation assembly 14 or a fluid tank 30 (as shown in FIG. 4). Additionally, a pressure sensor may be located proximate and in operable communication with a container 12 surface to which a solar energy generation assembly 14 is attached or within a tracking assembly 24.

Referring now to FIGS. 2A-2E, the internal frame 18 is shown and described in greater detail. In FIG. 2A, a solar energy generation assembly 14 affixed to an internal frame 18 is shown. To better show the components, the solar energy generation assembly 14 is shown in FIG. 2A without the solar modules 46. The solar energy generation assembly 14 may be coupled to the shaft 52, which may, in turn, be coupled to the internal frame 18. The internal frame 18 may generally include two base components 60, a saddle 62, and a stabilization ring 64. The base components 60 may be have, for example, an A-frame shape, as shown in FIG. 2A, and each base component 60 may include two legs 66. Each base component 60 may be in contact with an inner surface of the container 12, as shown in FIG. 2B. Further, each base component 60 may include a cross beam 68 (also as shown in FIG. 2A). The base of each leg 66 may be cut at an angle, for example, a 45-degree angle (as shown in FIG. 2A). Further, the longer side of each leg 66 may be coupled to an anchor plate 70, which may be, in turn, coupled to the container 12 (as shown in FIGS. 2B and 2C). Although FIG. 2A shows the stabilization ring 64 directly coupled to the saddle 62, a portion of the container 12 alternatively may be disposed between the saddle 62 and the stabilization ring 64, as shown and described in FIGS. 2B-2E.

Continuing to refer to FIG. 2A, the photovoltaic frame 50 may include one or more primary portions 50A that may be coupled to the tracking assembly 24 and/or the shaft 52, and one or more secondary portions 50B that may be affixed to the primary portions 50A and the solar modules 46.

Referring now to FIG. 2B-2C, a front and side view of an internal frame 18 are shown. FIG. 2C shows a close-up view of the stabilization ring 64 of the internal frame 18. As shown in FIGS. 2A and 2B, the internal frame 18 may be disposed within the container 12. For example, the substantially hollow space within the container 12 is depicted with the reference number 67. The internal frame 18 may be permanently disposed within the container 12, regardless of whether the system 10 is assembled or disassembled. For example, the saddle 62 of each internal frame 18 may be bolted, screwed, welded, or otherwise affixed to the container 12, and the base components 60 may be bolted, screwed, welded, or otherwise affixed to the saddle 62. Alternatively, both the base components 60 and saddle 62 may be bolted, screwed, welded or otherwise affixed to the container 12. Further, the legs 66 of the base components 60 may be substantially orthogonal to the floor 72 of the container 12 and substantially parallel to the side walls 74 of the container 12. That is, the legs 66 may be at right angles (ninety degrees) to the floor 72 of the container 12. Alternatively, the legs 66 may be at an angle from the side walls 74 of the container 12 that is less than ninety degrees. However, this angle should not be more than 30 degrees from the vertical axis 76. This permanent coupling of the internal frame 18 to the inside of the container 12 may increase the stability of the system 10 when assembled and may reduce jostling, vibration, and shifting during transport when the system 10 is disassembled. Additionally, the internal frame 18 and system 10 as shown and described herein are able to withstand wind gusts of approximately 143 mph for approximately 3 seconds, making the system 10 suitable for applications in any area that is prone to hurricanes, for example, the United States and the Caribbean.

Referring now to FIGS. 2D and 2E, a close-up view and a cross-sectional view of the stabilization ring are shown, respectively. The image in FIG. 2D is as viewed along line 3D-3D in FIG. 2B. The stabilization ring 64 may be affixed to an outer surface of the container 12 only when the system 10 is assembled. For example, a stabilization ring 64 may be coupled to the top surface 78 of the container 12 around each aperture 54, as shown in FIG. 2C. Further, each stabilization ring 64 may include a plurality of holes 80 to accommodate a plurality of bolts or screws for fastening the stabilization ring 64 to the top surface 78 of the container 12. Each stability ring 64 may additionally include a plurality of fins 82 that extend upward from the top surface 78 of the container 12 (that is, in a direction that is substantially orthogonal to the plane of the top surface 78 of the container 12) so as to stabilize the shaft 52 when the system 10 is assembled. As shown in FIG. 2C, each fin 82 may be tapered distal of the top surface 78 of the container 12.

During assembly, the one or more apertures 54 may be uncovered, for example, by removing a plug or other means 56 for sealing the aperture 54. Then, a stabilization ring 64 may be coupled to an outer surface of the container 12 (for example, the upper surface 78 of the container 12) using one or more bolts, screws, welding, or other fastening means. For example, bolts may be advanced through pre-drilled holes 80 in the stabilization ring 64, through pre-drilled holes in the container 12, and through pre-drilled holes in the saddle 62. Thus, the shaft 52 may be coupled to the saddle 62. Additionally, the saddle 62 may include a recess sized to receive the shaft 52 (not shown). For example, the diameter of the saddle recess may be only slightly bigger (such as approximately 1 mm to approximately 5 mm) than the diameter of the shaft 52 so as to prevent shifting or tilting of the shaft 52 when the system 10 is assembled. Next, the shaft 52 of each solar energy generation assembly 14 may be inserted through an aperture 54 in the container 12, through the stabilization ring 64, until the shaft 52 is in contact with the saddle 62. If the saddle 62 includes an aperture for receiving the shaft 52 that does not extend all the way through the saddle 62, the lower surface of the saddle 62 may prevent the shaft 52 from going any farther into the interior of the container 12. Then, the tracker assembly 24, plurality of photovoltaic cells 48, and photovoltaic frame 50 may be assembled and mounted atop the shaft 52. Put another way, the proximal end 84 of the shaft 52 may be coupled to the container 12, whereas the tracker assembly 24, photovoltaic cells 48, and photovoltaic frame 50 may be coupled to the distal end 86 of the shaft 52. When in the assembled configuration, the longitudinal axis 87 of the shaft 52 may be substantially orthogonal to the plane in which the container top surface 78 lies.

Referring now to FIG. 3, a second embodiment of a portable energy generation system 10 is shown. The system 10 shown in FIG. 3 is substantially the same as that shown and described in FIG. 1, except that only one solar energy generation assembly 14 is included with the system 10. This allows for the use of a smaller container 12, which may be desirable depending on the area of the desired location, ease of transportation, cost, and other factors.

Referring now to FIGS. 4 and 5, a third and fourth embodiments of a portable energy generation system 10 is shown. As described above, each solar power generation assembly 14 may be any device or combination of devices capable of directly converting sunlight or solar heat into electricity. This includes, but is not limited to, photovoltaic cells, solar modules, solar thermal collectors (for example, flat plate collectors, parabolic troughs, and parabolic dishes), or heliostats with associated predetermined target (for example, a solar power tower). FIG. 4 shows a system 10 having two parabolic trough-style solar thermal collectors 14 and FIG. 5 shows a system 10 having one parabolic dish-style solar thermal collector 14. For simplicity, the internal frame 18 is not shown in FIGS. 4 and 5. The systems 10 of FIGS. 4 and 5 may also include one or more fluid tanks 30, one or more pumps 72, and one or more turbines 36 or other rotary mechanical devices that extract energy from fluid flow and convert it to useful work, and one or more generators 74 powered by the one or more turbines 36. For example, the turbine 36 may be capable of producing energy from heated water (steam), liquid sodium, molten salts, or other energized fluid. Electricity generated by the one or more generators 74 may then be stored in one or more batteries 20 as described above for FIG. 1. In the system 10 of FIG. 5, the parabolic dish may be coupled to a single shaft 52 as shown and described, for example, in FIGS. 2A-2E, or it may be coupled to two or more shafts 52, as shown in FIG. 5. In that case, each shaft 52 may pass through a stabilization ring 64 and be coupled to the internal frame 18. Further, wires 32 leading from the solar power generation assembly 14 may be routed through the shaft 52 or though a pre-cut aperture 54 in the container 12. All other features, including the tracking feature, are the same as shown and described in FIG. 1.

Referring now to FIG. 6, a fifth embodiment of a portable energy generation system 10 is shown. Rather than a single container 12 holding one or more solar energy generation assemblies 14, the system 10 shown in FIG. 6 includes one or more containers 12 (for example, two containers 12 are shown) and a single solar energy generation assembly 14. The assembly 14 may be larger than those shown and described in FIGS. 1-5, the components of which sized to fit within more than one container 12 when disassembled. However, each container 12 may include an internal frame 18. All other components of the system 10 may be as shown and described in FIGS. 1-5.

Continuing to refer to FIG. 6, the solar energy generation assembly 14, when assembled, is removably coupled to both (or all, if more than two containers 12 are used) containers 12, with the weight of the assembly 14 being distributed substantially equally between the containers 12. The system 10 of FIG. 6 may also include one or more support beams 76 for providing additional support of the assembly 14. The entire system 10 may be used as a temporary shelter or storage area.

Referring now to FIGS. 7-10, exemplary configurations of a plurality of portable energy generation systems 10 are shown. A plurality of systems 10 may be configured as an array in any manner, and the configurations shown herein are merely non-limiting examples. Each system 10 may be in electrical communication with the other systems 10 or may operate independently, as described above in FIG. 1. Further, the systems 10 may be tethered or otherwise secured to the other systems 10. Except as otherwise noted, the systems 10 of FIGS. 7-10 are as described in FIGS. 1-6.

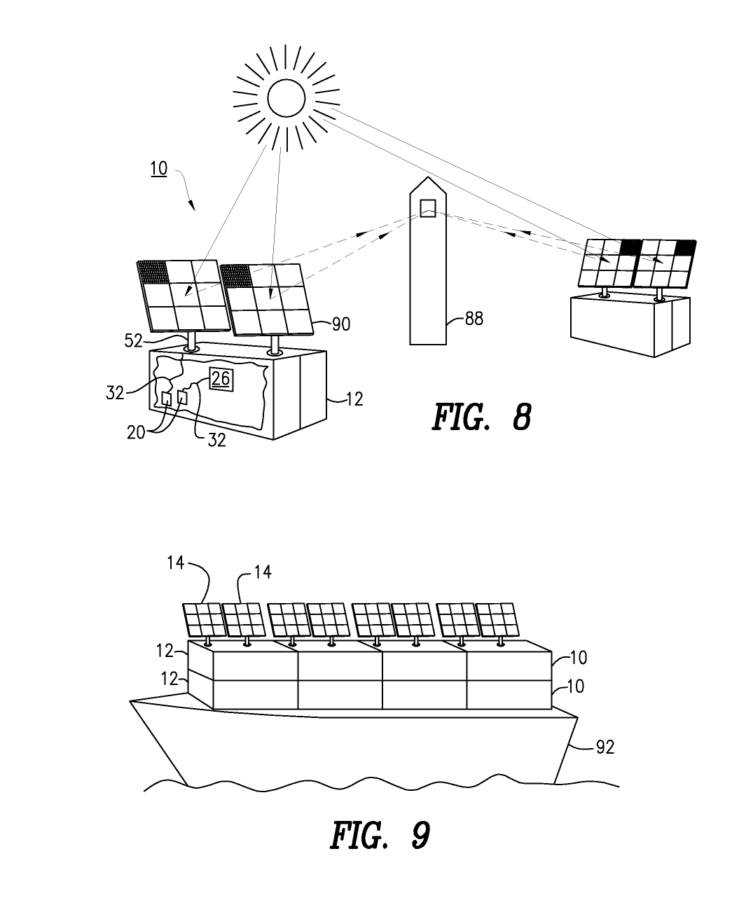

In the configuration of FIG. 7, a plurality of systems 10 (for example, those shown in FIG. 1) is arranged linearly. A space between each system 10 may be used, for example, to store equipment or provide space for vehicles, as shown. In the configuration of FIG. 8, a plurality of systems 10 is arranged about a power tower 88. Each of the systems of FIG. 8 includes one or more heliostats 90. These systems 10 may not generate electricity themselves, but instead contribute to electricity production by a power tower 88. As such, these systems 10 may not include power inverters 16, batteries for storing generated electricity 20, or charge controllers 22. These systems 10 may include, however, one or more batteries 20 for powering one or more computers or user input devices 26 and/or tracker assemblies 24. When the system 10 of FIG. 8 is disassembled and packed within the container 12, the power tower 88 may or may not also be included within the container 12. For example, the power tower 88 may be sized to fit within the container 12 when the system 10 is disassembled, or it may be a large, permanent fixture that is not sized to fit within the container 12 (for example, as shown in FIG. 8).

In the configuration of FIG. 9, a plurality of systems 10 is shown on a shipping vessel 92. The uppermost systems 10 are shown assembled, the containers 12 of which are stacked on top of a number of disassembled systems 10 still packaged within containers 12. This configuration may be possible, for example, when transporting one or more systems 10 to a desired location. Depending on the number of systems 10 and the configuration thereof, one or more systems 10 may be assembled and actively generating power during transport. It will be understood that the systems 10 are not necessarily stacked on top of each other on a shipping vessel, and may instead be used individually or in an array aboard any ship, barge, or land or air vehicle. Thus, electricity may be generated while a system 10 is mobile, allowing for delivery of a system with fully charged batteries 18 and/or heated liquid within a tank 30, for example. Additionally, one or more systems 10 may be in electrical communication with the vehicle itself, thereby powering or helping to power the vehicle during transport.

In the configuration of FIG. 10, a plurality of assembled systems 10 is shown floating in a body of water 94. The systems 10 may be tethered or otherwise attached to each other to prevent the separation and/or loss of any system 10. As a non-limiting example, a floating array 96 may be assembled and launched from a transport vessel 92 as described above in FIG. 9. Such a floating array 96 may be anchored in place to provide power to drilling operations, underwater expeditions, aquatic reconnaissance missions, or construction activities. Alternatively, the floating array may be unanchored and carried by sea currents and used to power research or surveying equipment.

All of the systems 10 and configurations described herein may be sold as a kit that includes all components required for the assembly of a completely operational portable energy generation system. For example, the system of FIG. 1 may be sold as a container 12 that contains within components of one or more solar energy generation assemblies 14 (for example, one or more solar modules 46 and/or photovoltaic cells 48 and frames 50), one or more tracking assemblies 24 (for example, one or more slew drives 38 and slew drive movement controllers 40), one or more internal frames 18, one or more shafts 52, electrical components such as one or more power inverters 16, batteries 20, charge controllers 22, wires 32, computers and/or user input devices 26, attachment components, and optionally one or more sensors 28. A kit for other types of systems 10 described herein may include one or more fluid tanks 30, other energy sources 34, turbines 36, pumps 72, generators 74, and/or support beams 76.

Although not explicitly shown or described herein, the portable energy generation system 10 may be used for a variety of practical applications. As non-limiting examples, the system 10 may be used as portable workshops or offices, medical stations or clinics (even including triage, emergency, or other facilities), refrigerated storage units for food, medicine, or other perishable items, public bathrooms, temporary or semi-permanent living quarters, pump stations for irrigation systems or the like, data storage units, electrical power source base units (for example, for powering emergency response equipment, cell phones, computers, etc.), and for any other purpose in which a portable and cost-effective energy source is required.

It will be appreciated by persons skilled in the art that the present invention is not limited to what has been particularly shown and described herein above. In addition, unless mention was made above to the contrary, it should be noted that all of the accompanying drawings are not to scale. A variety of modifications and variations are possible in light of the above teachings without departing from the scope and spirit of the invention, which is limited only by the following claims.

What is claimed is:

1. A portable energy generation system comprising:
a portable container having an outer surface and an inner surface and defining an internal space; and
a solar energy generation assembly,
the portable energy system having a disassembled configuration and an assembled configuration, the solar energy generation assembly being removably coupled to the external surface of the portable container and the solar energy generation assembly producing electricity when the system is in the assembled configuration.

2. The portable energy generation system of claim 1, further comprising an internal frame, the internal frame being coupled to the container with the internal space, the solar energy generation assembly being coupled to the internal frame when the portable energy system is in the assembled configuration.

3. The portable energy generation system of claim 2, further comprising a shaft and a stabilization ring, the shaft being coupled to the internal frame, passing through the stabilization ring, and extending beyond the outer surface of the container.

4. The portable energy generation system of claim 3, wherein the outer surface of the container includes a container top portion defining a plane, and the shaft extends from the container top portion in a direction that is substantially orthogonal to the plane of the container top portion.

5. The portable energy generation system of claim 2, wherein the solar energy generation assembly stores the produced electricity within the internal space of the container.

6. The portable energy generation system of claim 2, wherein the internal space of the container is sized to contain the solar energy generation assembly when the system is in the disassembled configuration.

7. The portable energy generation system of claim 2, wherein the solar energy generation assembly includes a plurality of photovoltaic cells and a frame.

8. The portable energy generation system of claim 2, further comprising a solar tracking assembly, the solar energy generation assembly being coupled to the solar tracking assembly.

9. The portable energy generation system of claim 2, wherein the portable energy generation system includes a plurality of solar energy generation assemblies and a plurality of solar tracking assemblies, each solar tracking assembly being selected from the group consisting of single-axis tracking assembly and dual-axis tracking assembly.

10. The portable energy generation system of claim 9, further comprising at least one power inverter and at least one battery in electrical communication with at least one of the plurality of solar energy generation assemblies.

11. The portable energy generation system of claim 2 wherein the solar energy generation assembly is a solar thermal collector.

12. The portable energy generation system of claim 11, further comprising at least one fluid tank, at least one rotary mechanical device, and at least one power generator.

13. The portable energy generation system of claim 12, further comprising at least one battery and a power inverter.

14. The portable energy generation system of claim 2, wherein the container is buoyant, the container sustaining buoyancy of the system when the system is in the disassembled configuration or the assembled configuration.

15. The portable energy generation system of claim 2, wherein the system includes a plurality of portable containers, the solar energy generation assembly being sized to fit within the plurality of containers when the system is in the disassembled configuration.

16. A portable energy generation system comprising:
a portable container;
a solar energy generation assembly including at least one reflective element; and
a predetermined target, the at least one reflective element redirecting sunlight to the predetermined target, the solar energy generation assembly producing electricity within the predetermined target.

17. The portable energy generation system of claim 16, wherein the solar energy generation assembly has a disassembled configuration and an assembled configuration, the solar energy generation assembly being removably coupled to an external surface of the portable container and redirecting sunlight to the predetermined target when the solar energy generation assembly is in the assembled configuration.

18. The portable energy generation system of claim 17, wherein the portable container is sized to contain the solar energy generation assembly when the solar energy generation assembly is in the disassembled configuration.

19. The portable energy generation system of claim 17, wherein the portable energy generation system includes a plurality of solar energy generation assemblies and a plurality of solar tracking assemblies, each solar energy generation assembly being coupled to a tracking assembly and the container is sized to contain within the plurality of solar energy generation assemblies and plurality of solar tracking assemblies when the portable energy generation assemblies are in the disassembled configuration.

20. The portable energy generation system of claim 17, wherein the reflective element is selected from the group consisting of a parabolic trough and parabolic dish.

21. A kit for the production of solar energy comprising:
a substantially hollow and portable container;
at least one solar energy generation assembly;
at least one internal frame;
at least one solar tracking assembly;
at least one battery;
the container being sized to accommodate within the at least one solar energy generation assembly, the at least one internal frame, the at least one solar tracking assembly, and the at least one battery.

22. The kit of claim 21, further comprising at least one power inverter, at least one charge controller, and attachment components, the container being sized to accommodate within the at least one solar energy generation assembly, the at least one solar tracking assembly, the at least one battery, the at least one power inverter, the at least one charge controller, and attachment components.

23. The kit of claim 21, further comprising at least one fluid tank, at least one pump, at least one rotary mechanical device, at least one generator, and attachment components, the container being sized to accommodate within the at least one solar energy generation assembly, the at least one solar tracking assembly, the at least one battery, the at least one fluid tank, the at least one pump, the at least one rotary mechanical device, the at least one generator, and attachment components.

24. The kit of claim 21, further comprising at least one of a gas generator, a diesel generator, and a fuel cell.
